(19) United States
(12) Patent Application Publication
(10) Pub. No.: US 2021/0285827 A1
(43) Pub. Date: Sep. 16, 2021

(54) DYNAMIC TEMPERATURE SENSOR

(71) Applicant: HONEYWELL INTERNATIONAL INC., Morris Plains, NJ (US)

(72) Inventors: Yubin LV, Morris Plains, NJ (US); Bo REN, Morris Plains, NJ (US); Junfeng WANG, Morris Plains, NJ (US); Li WANG, Morris Plains, NJ (US)

(21) Appl. No.: 16/317,158

(22) PCT Filed: Jul. 12, 2016
(86) PCT No.: PCT/CN2016/089763

§ 371 Date: Jan. 11, 2019

(51) Int. Cl. G01K 7/25; G05F 1/10

(52) U.S. Cl. CPC G01K 7/25; G01K 2219/00; G05F 1/10

(57) ABSTRACT

Devices, methods, systems, and computer-readable media for a dynamic temperature sensor are described herein. One or more embodiments include a device, comprising: a controller that includes a variable voltage output coupled to a sensor, wherein the controller provides a voltage segment to the sensor based on a signal of the sensor received at the controller.

### TECHNICAL FIELD

The present disclosure relates to methods, devices, system, and computer-readable media for a dynamic temperature sensor.

### BACKGROUND

Sensors can be utilized to detect events or changes in a particular environment. In some examples, sensors can utilize electrical or optical signals that can vary based on the environment. In some examples, a sensor can be coupled to a controller that receives the signals. In these examples, the controller can receive the signal and determine a corresponding attribute of the environment based on the signal.

### BRIEF DESCRIPTION OF THE DRAWINGS

FIG. 1 is an example of a system for a dynamic temperature sensor consistent with the present disclosure.

FIG. 2 is an example of a system for a dynamic temperature sensor consistent with the present disclosure.

FIG. 3 is an example of a system for a dynamic temperature sensor consistent with the present disclosure.

FIG. 4 is an example of a method for a dynamic temperature sensor consistent with the present disclosure.

FIG. 5 is an example of a method for a dynamic temperature sensor consistent with the present disclosure.

FIG. 6 is an example of a diagram of a computing device for a dynamic temperature sensor consistent with one or more embodiments of the present disclosure.

### DETAILED DESCRIPTION

Devices, methods, systems, and computer-readable media for a dynamic temperature sensor are described herein. One or more embodiments include a device, comprising: a controller that includes a variable voltage output coupled to a sensor, wherein the controller provides a voltage segment to the sensor based on a signal of the sensor received at the controller. In some examples, the variable voltage output can be a digital to analog output coupled to the controller to provide the voltage segment to the sensor. In some examples, the variable voltage output can include filter circuit.

In some examples, the controller can utilize a number of signal thresholds to alter the voltage segment or voltage provided to the sensor based on the signal received from the sensor. In some examples, the controller can alter the voltage segment or voltage provided to the sensor to measure a particular range of signals from the sensor and/or measure a particular range of temperatures. For example, the controller can utilize a first voltage segment to measure a first range of temperatures and utilize a second voltage segment to measure a second range of temperatures. In another example, the controller can utilize a first voltage segment when a signal within a first range of signals is received from the sensor and utilize a second voltage segment when a signal within a second range of signals is received from the sensor.

In some examples, the variable voltage output provided to the sensor can increase performance and accuracy of the dynamic temperature sensor as described herein. In some examples, the dynamic temperature sensor described herein can reduce maxim error from 2.47% to 0.57% compared to previous systems. In addition, the dynamic temperature sensor described herein can reduce absolute error from 0.52% to 0.18% compared to previous systems. In some examples, increasing the number of voltage segments utilized by the controller can increase the accuracy of the dynamic temperature sensor. However, increasing the number of voltage segments can also increase processing time and/or power consumption of the dynamic temperature sensor.

In the following detailed description, reference is made to the accompanying drawings that form a part hereof. The drawings show by way of illustration how one or more embodiments of the disclosure may be practiced.

These embodiments are described in sufficient detail to enable those of ordinary skill in the art to practice one or more embodiments of this disclosure. It is to be understood that other embodiments may be utilized and that process changes may be made without departing from the scope of the present disclosure.

As will be appreciated, elements shown in the various embodiments herein can be added, exchanged, combined, and/or eliminated so as to provide a number of additional embodiments of the present disclosure. The proportion and the relative scale of the elements provided in the figures are intended to illustrate the embodiments of the present disclosure, and should not be taken in a limiting sense.

The figures herein follow a numbering convention in which the first digit corresponds to the drawing figure number and the remaining digits identify an element or component in the drawing. Similar elements or components between different figures may be identified by the use of similar remaining digits.

As used herein, “a” or “a number of” something can refer to one or more such things. For example, “a number of devices” can refer to one or more devices. Additionally, the designator “N”, as used herein, particularly with respect to reference numerals in the drawings, indicates that a number of the particular feature so designated can be included with a number of embodiments of the present disclosure.

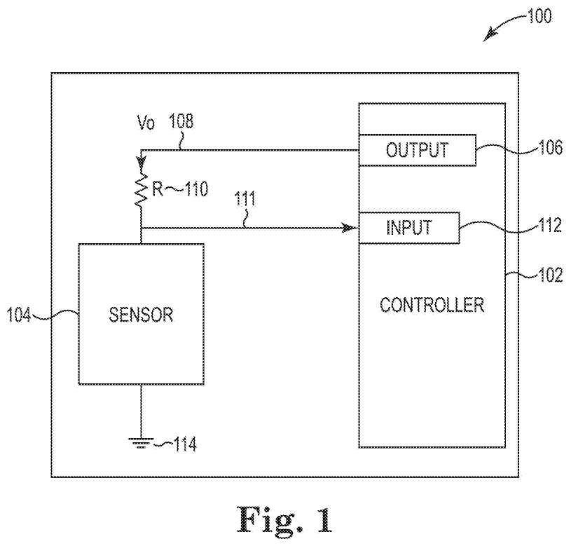

FIG. 1 is an example of a system 100 for a dynamic temperature sensor consistent with the present disclosure. In some examples, the system 100 can be utilized to calculate a total dissolved solids (TDS) measurement based on a temperature of a liquid. In some examples, the system 100 can provide a more accurate measurement of the temperature and thus a more accurate TDS measurement compared to previous systems and methods. In some examples, the system 100 can be utilized to adjust an output voltage provided to a sensor 104 in real time to obtain a more accurate TDS measurement. Even though a temperature sensor is utilized for examples herein, the system 100 can utilize other sensors in a similar manner.

In some examples, the system 100 can include a controller 102. In some examples, the controller 102 can be a computing device as described herein. In some examples, the controller 102 can be a microcontroller unit (MCU) that can be utilized to receive signals from a sensor 104. In some examples, the controller 102 can include an output 106 to provide power to the sensor 104 via a connection 108 (e.g., electrical connection, etc.) at a particular output voltage (Vo). In some examples, the controller 102 can be coupled to a first side of a resistor 110 via the connection 108. For example, the controller 102 can utilize the output 106 to provide a particular output voltage to the first side of the resistor 110.

In some examples, the resistor 110 can be an embedded resistor within the system 100. For example, the resistor 110 can be soldered into the system. In some examples, the resistor 110 can provide a constant resistance for the system 100. For example, the resistor 110 can be passive two-terminal resistor that provides approximately 5 kilohms of resistance. In this example, the resistance of the resistor 110 may not be able to be adjusted (e.g., non-adjustable resistor, passive resistor, etc.).

In some examples, the controller 102 can include an input 112 that is coupled to the sensor 104. In some examples, the controller 102 can be coupled to a position between the sensor 104 and the resistor 110 by a connection 111 (e.g., electrical connection, etc.). In some examples, the input 112 can be utilized to receive signals (e.g., voltage signals, voltage input, etc.) from the sensor 104. In some examples, the input 112 can be coupled to a second side of the resistor 110 between the sensor 104 and the resistor 110 to receive an input voltage of the system 100. In some examples, the input 112 can be an analog to digital converter (ADC) input. In some examples, the controller 102 can utilize signals received at the input 112 to calculate a TDS measurement for a liquid. In some examples, the controller 102 can receive signals in the form of an input voltage from the sensor 104. In some examples, the input voltage from the sensor can be based on Equation 1.

Vᵢₙ=Vₒ×Rₓ/(R+Rₓ) Equation 1

Equation 1 can be utilized to solve for the input voltage (Vᵢₙ) by utilizing the output voltage (Vₒ), the resistance (R) of the resistor 110, and the resistance (Rₓ) of the sensor 104. As described herein, the resistance (Rₓ) of the sensor 104 can correspond to a particular temperature of a liquid surrounding the sensor 104 and/or area surrounding the sensor 104. For example, a relatively lower temperature can cause the sensor 104 to have a relatively high resistance. In another example, a relatively high temperature can cause the sensor 104 to have a relatively low resistance. Thus, a corresponding temperature can be determined based on the voltage input (Vin) received by the sensor 104 at the input 112 of the controller 102.

In some examples, the sensor 104 can be coupled to an electrical ground 114. In some examples, the sensor 104 can be a negative temperature coefficient (NTC) thermistor that can exhibit a particular resistance when exposed to a particular temperature. In these examples, the voltage received at the input 112 can correspond to the resistance provided by the sensor 104, which can be utilized by the controller 102 to determine a temperature of a liquid or area surrounding the sensor 104.

In some examples, the output 106 can be a digital to analog converter (DAC) that can provide a particular voltage or voltage segment from a plurality of voltages or voltage segments. For example, the controller 102 can utilize the output 106 to provide a first voltage segment to the sensor 104 or a second voltage segment to the sensor 104 based on received signals (e.g., voltage input, voltage signal based on sensor 104 resistance, etc.) from the sensor 104. That is, the output 106 can be a variable voltage output that can be adjusted by the controller 102 to provide a particular voltage segment to the sensor 104.

As used herein, a voltage segment can be a designated voltage utilized by the controller 102 to adjust an output voltage based on a signal received from the sensor 104. For example, the controller 102 can utilize a first voltage segment corresponding to a first voltage and a second voltage segment corresponding to a second voltage. In this example, the controller 102 can utilize the first voltage segment to provide the first voltage to the sensor 104. In this example, the controller 102 can receive a number of signals from the sensor 104 utilizing the first voltage and alter to the second voltage segment to provide the second voltage to the sensor 104 based on the received number of signals. In this way the controller 102 can provide dynamic voltage to the sensor 104 based on signals received from the sensor 104.

In some examples, the controller 102 can utilize a number of thresholds (e.g., signal thresholds, etc.) to determine a voltage segment from a number of voltage segments to provide to the sensor 104. In some examples, the number of thresholds can correspond to a voltage signal received at the input 112. For example, the controller 102 can determine when the voltage signal from the sensor 104 is below a first threshold. In this example, the controller 102 can increase the output voltage to the sensor 104 to increase the voltage signal from the sensor 102. In some examples, the controller 102 can utilize a method as described herein to dynamically adjust the output voltage to increase the accuracy of the system 100.

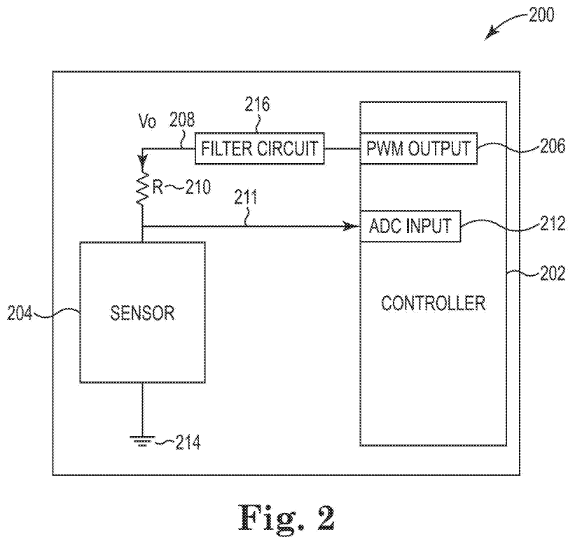

FIG. 2 is an example of a system 200 for a dynamic temperature sensor consistent with the present disclosure. In some examples, the system 200 can include the same or similar features as system 100 as referenced in FIG. 1. In some examples, the system 200 can be utilized to calculate a total dissolved solids (TDS) measurement based on a temperature of a liquid. In some examples, the system 200 can provide a more accurate measurement of the temperature and thus a more accurate TDS measurement compared to previous systems and methods. In some examples, the system 200 can be utilized to adjust an output voltage provided to a sensor 204 in real time to obtain a more accurate TDS measurement.

In some examples, the system 200 can provide a variable voltage output (Vo) via a connection 208 as described herein. In addition, the system 200 can provide the voltage output to a first side of a resistor 210. In some examples, the system 200 can utilize the sensor 204 to measure attributes of an area surrounding the sensor 204. For example, the system 200 can utilize a NTC thermistor as the sensor 204 to measure a temperature of liquid surrounding the sensor 204. As described herein, the sensor 204 can change a resistance (Rx) as the temperature of the liquid changes and the signal or voltage received at the input 212 (e.g., ADC input, etc.) can correspond to a particular temperature of the liquid. As described herein, the input 212 can receive signals from the sensor 204 via a connection 211 that is located between the resistor 210 (e.g., second side of the resistor 210) and the sensor 204. In addition, the sensor 204 can be coupled to an electrical ground 214.

In some examples, the system 200 can also include a filter circuit 216 coupled between the first side of the resistor 210 and a pulse width modulation (PWM) output 206. In some examples, the PWM output 206 can be utilized to deliver power to the first side of the resistor 210 utilizing a PWM power delivery technique. In some examples, the PWM output 206 can be utilized to regulate the voltage output as described herein. For example, the PWM output 206 can alter the voltage output to a number of different voltage segments based on a signal received by the sensor 204 as described herein.

In some examples, the PWM output 206 can be coupled to the filter circuit 216. In some examples, the filter circuit 216 can be a passive low pass filter. In some examples, the filter circuit 216 can be utilized to filter a number of frequencies output by the PWM output 206. For example, the filter circuit 216 can modify, reshape, or reject unwanted frequencies that are provided by the PWM output 206.

As described herein, the controller 202 can utilize a number of thresholds to determine a voltage segment from a number of voltage segments to provide to the sensor 204. In some examples, the number of thresholds can correspond to a voltage signal received at the input 212. For example, the controller 202 can determine when the voltage signal from the sensor 204 is below a first threshold. In this example, the controller 202 can increase the output voltage to the sensor 204 to increase the voltage signal from the sensor 202. In some examples, the controller 202 can utilize a method as described herein to dynamically adjust the output voltage to increase the accuracy of the system 200.

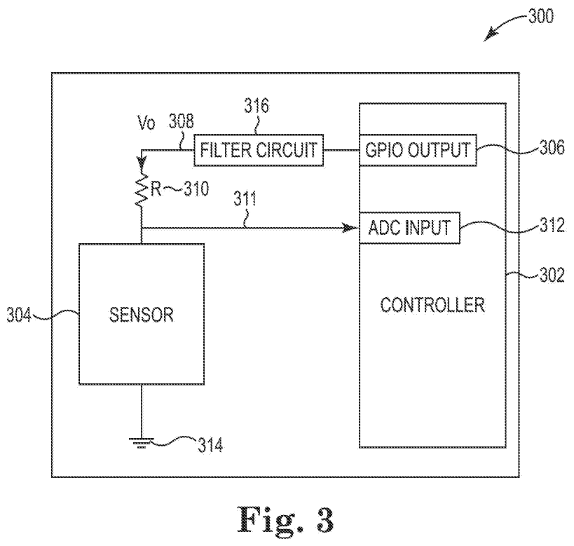

FIG. 3 is an example of a system for a dynamic temperature sensor consistent with the present disclosure. In some examples, the system 300 can include the same or similar features as system 100 as referenced in FIG. 1 and/or the system 200 as referenced in FIG. 2. In some examples, the system 300 can be utilized to calculate a total dissolved solids (TDS) measurement based on a temperature of a liquid. In some examples, the system 300 can provide a more accurate measurement of the temperature and thus a more accurate TDS measurement compared to previous systems and methods. In some examples, the system 300 can be utilized to adjust an output voltage provided to a sensor 304 in real time to obtain a more accurate TDS measurement.

In some examples, the system 300 can provide a variable voltage output (Vo) via a connection 308 as described herein. In addition, the system 300 can provide the voltage output to a first side of a resistor 310. In some examples, the system 300 can utilize the sensor 304 to measure attributes of an area surrounding the sensor 304. For example, the system 300 can utilize a NTC thermistor as the sensor 304 to measure a temperature of liquid surrounding the sensor 304. As described herein, the sensor 304 can change a resistance (Rx) as the temperature of the liquid changes and the signal or voltage received at the input 312 (e.g., ADC input, etc.) can correspond to a particular temperature of the liquid. As described herein, the input 312 can receive signals from the sensor 304 via a connection 311 that is located between the resistor 310 (e.g., second side of the resistor 310) and the sensor 304. In addition, the sensor 304 can be coupled to an electrical ground 314.

In some examples, the system 300 can also include a filter circuit 316 coupled between the first side of the resistor 310 and a general purpose input/output port (GPIO) output 306. In some examples, the GPIO output 306 can be utilized to deliver power to the first side of the resistor 310 utilizing a GPIO power delivery technique. In some examples, the GPIO output 306 can be utilized to regulate the voltage output as described herein. For example, the GPIO output 306 can alter the voltage output to a number of different voltage segments based on a signal received by the sensor 304 as described herein.

In some examples, the GPIO output 306 can be coupled to the filter circuit 316. In some examples, the filter circuit 316 can be a passive low pass filter. In some examples, the filter circuit 316 can be utilized to filter a number of frequencies output by the GPIO output 306. For example, the filter circuit 316 can modify, reshape, or reject unwanted frequencies that are provided by the GPIO output 306.

As described herein, the controller 302 can utilize a number of thresholds to determine a voltage segment from a number of voltage segments to provide to the sensor 304. In some examples, the number of thresholds can correspond to a voltage signal received at the input 312. For example, the controller 302 can determine when the voltage signal from the sensor 304 is below a first threshold. In this example, the controller 302 can increase the output voltage to the sensor 304 to increase the voltage signal from the sensor 302. In some examples, the controller 302 can utilize a method as described herein to dynamically adjust the output voltage to increase the accuracy of the system 300.

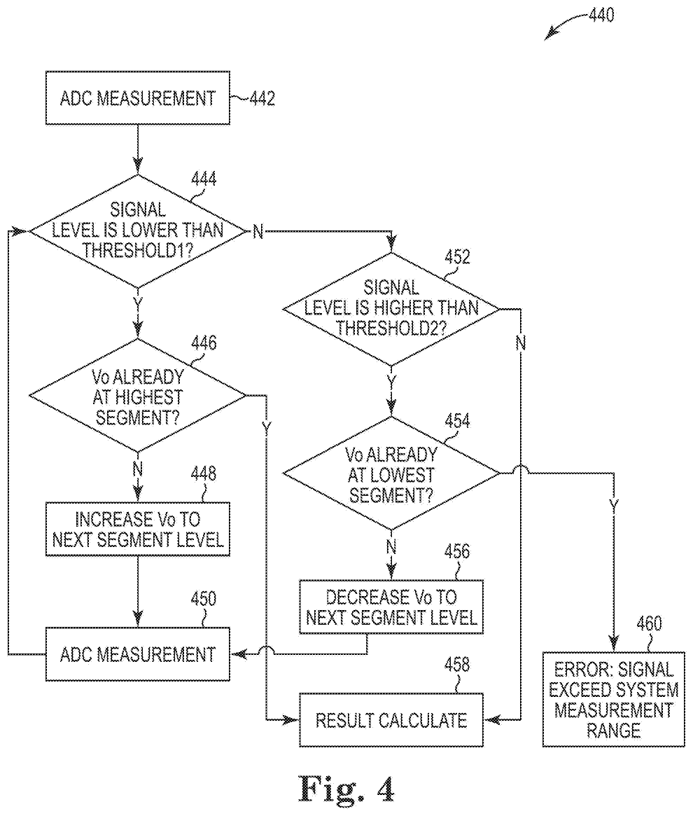

FIG. 4 is an example of a method 440 for a dynamic temperature sensor consistent with the present disclosure. In some examples, the method 440 can be performed or executed by a computing device. For example, the method 440 can be executed by a controller 102 as referenced in FIG. 1, a controller 202 as referenced in FIG. 2, and/or a controller 302 as referenced in FIG. 3.

In some examples, the method 440 can begin by taking an analog to digital converter (ADC) measurement at 442. In some examples, taking an ADC measurement can include receiving a voltage signal from a sensor. For example, a controller input (e.g., input 112 as referenced in FIG. 1, etc.) can receive a voltage signal between a resistor and a sensor. In this example, the voltage signal can correspond to a particular temperature surrounding the sensor when the sensor alters a resistance based on a surrounding temperature. In some examples, the voltage signal can be based on Equation 1 as described herein.

In some examples, method 440 can include determining whether the signal level (e.g., level of the voltage signal, etc.) is lower than a first threshold at 444. In some examples, the first threshold can be a low level threshold for a system as described herein. For example, a signal level below the first threshold may not provide as accurate of an ADC measurement compared to a signal level above the first threshold. In some examples, the first threshold can be approximately 2.0 Volts (V).

When the signal level is lower than the first threshold, the method 440 can determine if the voltage output (Vo) is at a highest voltage segment from a number of voltage segments at 446. As described herein, a controller can utilize a number of voltage segments to provide a particular voltage output to a sensor. For example, the controller can utilize three different voltage segments with three different corresponding voltages. In this example, a first segment can be a lowest segment, a second segment can be a middle segment, and a third segment can be a highest segment. When the output voltage is at a highest voltage segment, the method 440 can calculate a result at 458. As used herein, calculating the result include determining a temperature of a liquid utilizing the sensor as described herein.

When the output voltage is not at the highest voltage segment, the method 440 can include increasing the voltage output to a next segment level that is one level higher at 448. In some examples, increasing the output voltage can include providing the sensor with a greater output voltage as described herein. When the output voltage is increased to a greater voltage segment, the method 440 can include taking an ADC measurement at 450 with the increased output voltage.

In some examples, the ADC measurement at 450 can be utilized to determine if the signal level is lower than the first threshold at 444. In some examples, when the signal level is not lower than the first threshold, the method 440 can determine if the signal level is higher than a second threshold at 452. In some examples, the second threshold can be a high level threshold for a system as described herein. For example, a signal level above the second threshold may not provide as accurate of an ADC measurement compared to a signal level below the second threshold. In some examples, a signal level above the second threshold can cause an error of the system or may not be able to be utilized for calculating a result as described herein. In some examples, the second threshold can be approximately 2.3 Volts (V).

In some examples, when the signal level is higher than the second threshold, the method 440 can determine if the output voltage is at a lowest voltage segment at 454. As described herein, a controller can utilize a number of voltage segments to provide a particular voltage output to a sensor. In some examples, when the output voltage is already at a lowest voltage segment, the method 440 can generate an error or failure alert of the system at 460. For example, when the signal level is higher than the second threshold and the output voltage segment is at a lowest voltage segment, a controller can determine that there is a system failure or that a measurement cannot be performed.

In some examples, when the output voltage is not at a lowest voltage segment, the method 440 can decrease the voltage by lowering the voltage to a next lowest voltage segment. When the voltage is decreased to a lower voltage segment, the method 440 can take an ADC measurement with the lower voltage segment at 450.

In some examples, the method 440 can be utilized to dynamically alter an output voltage to a sensor based on the received signal from the sensor. In some examples, the method 440 can be utilized by a controller to increase an accuracy of the calculated results at 458.

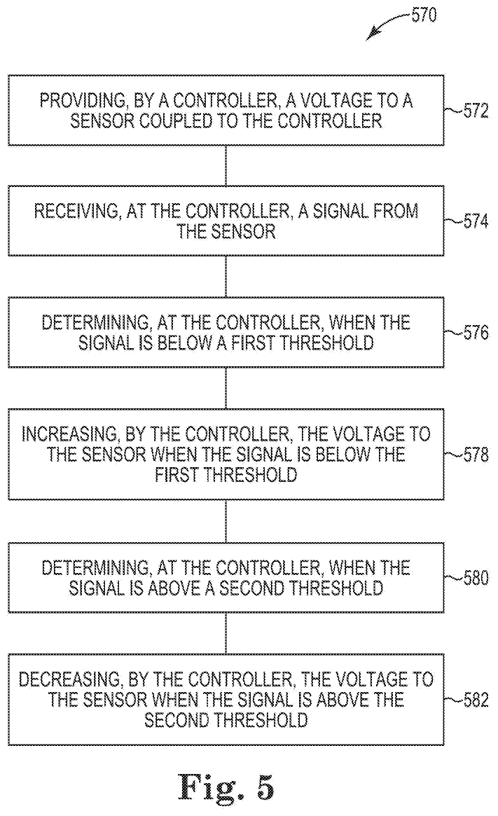

FIG. 5 is an example of a method 570 for a dynamic temperature sensor consistent with the present disclosure. In some examples, the method 570 can be performed or executed by a computing device. For example, the method 570 can be executed by a controller 102 as referenced in FIG. 1, a controller 202 as referenced in FIG. 2, and/or a controller 302 as referenced in FIG. 3.

At 572, the method 570 can include providing, by a controller, a voltage to a sensor coupled to the controller. As described herein, the controller can provide power to the sensor via an output coupled to the controller. In some examples, the controller can provide the voltage to a first side of a resistor. In some examples, the sensor can be coupled to a second side of the resistor.

At 574, the method 570 can include receiving, at the controller, a signal from the sensor. As described herein, the controller can receive a signal such as a voltage signal from the sensor. In some examples, the signal can be based on a temperature surrounding the sensor. In some examples, the signal can correspond to a resistance of the sensor, which can correspond to the temperature surrounding the sensor.

At 576, the method 570 can include determining, at the controller, when the signal is below a first threshold. As described herein, the controller can utilize a number of threshold values to determine when to alter the voltage provided to the sensor. In some examples, the first threshold can be a low threshold value as described herein.

At 578, the method 570 can include increasing, by the controller, the voltage to the sensor when the signal is below the first threshold. As described herein, the first threshold can be a low threshold value and the controller can increase the voltage to the sensor. In some examples, the controller can increase to a higher voltage segment. In some examples, the controller can increase to a next highest voltage segment.

At 580, the method 570 can include determining, at the controller, when the signal is above a second threshold. In some examples, the second threshold can be a high threshold value. As described herein, a signal that is above the second threshold can cause an error or indicate that there is a system failure when the controller is already providing a lowest voltage segment.

At 582, the method 570 can include decreasing, by the controller, the voltage to the sensor when the signal is above the second threshold. As described herein, the controller can decrease the voltage provided to the sensor. In some examples, the controller can decrease the voltage segment to a next lowest voltage segment.

In some examples, the method 570 can include determining, by the controller, when the signal is less than the first threshold and the voltage is at a maximum voltage. As described herein, the controller can receive a signal from the sensor can determined when the signal is less than a first threshold. As described herein, the first threshold can be approximately 2.0 Volts. In some examples, increasing the voltage can increase the accuracy of the system as described herein. In some examples, the controller can determine that the voltage or voltage segment is at a max voltage segment.

In some examples, the method 570 can include generating, by the controller, a sensor result at the maximum voltage. In some examples, the controller can determined that the output voltage is at a maximum voltage and/or a maximum voltage segment. In these examples, the controller can determine that a measurement should be taken at the maximum voltage or maximum voltage segment.

In some examples, the method 570 can include determining, by the controller, when the signal is greater than the second threshold and the voltage is at a minimum voltage. As described herein, the second threshold can be approximately 2.3 Volts. In some examples, the controller can alter the output voltage based on the signal. In some examples, the controller can alter the output voltage to a minimum voltage and/or minimum voltage segment.

In some examples, the method 570 can include generating, by the controller, a sensor fault based on the determination. In some examples, when the controller has altered the output voltage to a minimum voltage and/or a minimum voltage segment and the signal is still greater than the second threshold, the controller can determine that there is a fault in the system.

In some examples, the method 570 can include generating, by the controller, a sensor result when the signal is greater than the first threshold and lower than the second threshold. In some examples, the controller can perform a measurement utilizing the signal from the sensor when the signal is greater than the first threshold and lower than the second threshold.

In some examples, the method 570 can be utilized to dynamically alter an output voltage to a sensor based on the received signal from the sensor. In some examples, the method 570 can be utilized by a controller to increase an accuracy of a system utilizing the sensor.

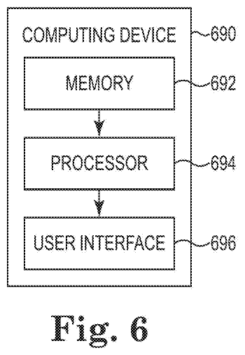

FIG. 6 is an example of a diagram of a computing device 690 for a dynamic temperature sensor consistent with one or more embodiments of the present disclosure. Computing device 690 can be, for example, an embedded system as described herein, among other types of computing devices. For example, the computing device 690 can be a controller (e.g., controller 102 as referenced in FIG. 1, controller 202 as referenced in FIG. 2, controller 303 as referenced in FIG. 3, etc.).

As shown in FIG. 6, computing device 690 includes a memory 692 and a processor 694 coupled to user interface 696. Memory 692 can be any type of storage medium that can be accessed by processor 694, which performs various examples of the present disclosure. For example, memory 692 can be a non-transitory computer readable medium having computer readable instructions (e.g., computer program instructions) stored thereon.

Processor 694 executes instructions to provide a variable voltage to a sensor based on signals from the sensor in accordance with one or more embodiments of the present disclosure. Processor 694 can also determine when a signal from the sensor is below a first threshold. Processor 694 can also increase or decrease a voltage to the sensor.

Further, although memory 692, processor 694 and user interface 696 are illustrated as being located in computing device 690, embodiments of the present disclosure are not so limited. For example, memory 692 can also be located internal to another computing resource (e.g., enabling computer readable instructions to be downloaded over the Internet or another wired or wireless connection). Part of the memory can be storage in a cloud storage. Processor 694 can be a cloud computer.

As shown in FIG. 6, computing device 690 can also include a user interface 696. User interface 696 can include, for example, a display (e.g., a screen, an LED light, etc.). The display can be, for instance, a touch-screen (e.g., the display can include touch-screen capabilities). User interface 696 (e.g., the display of user interface 696) can provide (e.g., display and/or present) information to a user of computing device 690.

Additionally, computing device 690 can receive information from the user of computing device 690 through an interaction with the user via user interface 696. For example, computing device 690 (e.g., the display of user interface 696) can receive input from the user via user interface 696. The user can enter the input into computing device 690 using, for instance, a mouse and/or keyboard associated with computing device 690, or by touching the display of user interface 696 in embodiments in which the display includes touch-screen capabilities (e.g., embodiments in which the display is a touch screen).

As used herein, “logic” is an alternative or additional processing resource to execute the actions and/or functions, etc., described herein, which includes hardware (e.g., various forms of transistor logic, application specific integrated circuits (ASICs), etc.), field programmable gate arrays (FPGAs), as opposed to computer executable instructions (e.g., software, firmware, etc.) stored in memory and executable by a processor.

Although specific embodiments have been illustrated and described herein, those of ordinary skill in the art will appreciate that any arrangement calculated to achieve the same techniques can be substituted for the specific embodiments shown. This disclosure is intended to cover any and all adaptations or variations of various embodiments of the disclosure.

It is to be understood that the above description has been made in an illustrative fashion, and not a restrictive one. Combination of the above embodiments, and other embodiments not specifically described herein will be apparent to those of skill in the art upon reviewing the above description.

The scope of the various embodiments of the disclosure includes any other applications in which the above structures and methods are used. Therefore, the scope of various embodiments of the disclosure should be determined with reference to the appended claims, along with the full range of equivalents to which such claims are entitled.

In the foregoing Detailed Description, various features are grouped together in example embodiments illustrated in the figures for the purpose of streamlining the disclosure. This method of disclosure is not to be interpreted as reflecting an intention that the embodiments of the disclosure require more features than are expressly recited in each claim.

Rather, as the following claims reflect, inventive subject matter lies in less than all features of a single disclosed embodiment. Thus, the following claims are hereby incorporated into the Detailed Description, with each claim standing on its own as a separate embodiment.

What is claimed:

1. A device comprising:
a controller that includes a variable voltage output coupled to a sensor wherein the controller provides a voltage segment to the sensor based on a signal of the sensor received at the controller.

2. The device of claim 1, wherein the variable voltage output comprises a digital to analog output.

3. The device of claim 1, wherein the variable voltage output comprises a filter circuit.

4. The device of claim 1, wherein the variable voltage output comprises a pulse width modulation (PWM) output coupled to the filter circuit.

5. The device of claim 1, wherein the variable voltage output comprises a general purpose input/output port (GPIO) coupled to the filter circuit.

6. The device of claim 1, wherein the sensor is coupled to an analog to digital converter of the controller.

7. The device of claim 1, wherein the sensor is a negative temperature coefficient (NTC) thermistor.

8. The device of claim 1, comprising an embedded resistor coupled between the variable voltage output and the sensor.

9. The device of claim 1, wherein the controller determines when the signal is below a first threshold.

10. The device of claim 1, wherein the controller alters the voltage segment when the signal is below the first threshold.

11. A system for a temperature sensor, comprising:
a negative temperature coefficient (NTC) sensor coupled to a variable voltage output of a controller and coupled to a signal input of the controller, wherein the controller provides a voltage from a voltage segment to the NTC sensor based on a signal received at the signal input.

12. The system of claim 11, wherein a 5 kilohm resistor is embedded between the NTC sensor and the variable voltage output of the controller.

13. The system of claim 11, wherein the signal input is an analog to digital converter (ADC) to receive the signal input from the NTC sensor.

14. The system of claim 13, wherein the ADC receives the signal as a voltage from the NTC sensor.

15. The system of claim 11, wherein the controller alters the voltage segment when the signal is lower than a first threshold and higher than a second threshold.

16. The system of claim 15, wherein the controller utilizes the second threshold to determine a system failure.

17. A method for a dynamic temperature sensor, comprising:
providing, by a controller, a voltage to a sensor coupled to the controller;
receiving, at the controller, a signal from the sensor;
determining, at the controller, when the signal is below a first threshold;
increasing, by the controller, the voltage to the sensor when the signal is below the first threshold;
determining, at the controller, when the signal is above a second threshold; and
decreasing, by the controller, the voltage to the sensor when the signal is above the second threshold.

18. The method of claim 17, comprising:
determining, by the controller, when the signal is less than the first threshold and the voltage is at a maximum voltage; and
generating, by the controller, a sensor result at the maximum voltage.

19. The method of claim 17, comprising:
determining, by the controller, when the signal is greater than the second threshold and the voltage is at a minimum voltage; and
generating, by the controller, a sensor fault based on the determination.

20. The method of claim 17, comprising generating, by the controller, a sensor result when the signal is greater than the first threshold and lower than the second threshold.
